(19) United States
(12) Patent Application Publication
(10) Pub. No.: US 2007/0120198 A1
(43) Pub. Date: May 31, 2007

(54) Latch-up prevention in semiconductor circuits

(75) Inventors: Ke-Yuan Chen, Banciao City (TW); Colin Thomas Bolger, Taipei (TW)

Correspondence Address: L. Howard Chen, Esq.;Kirkpatrick & Lockhart Preston Gates Ellis LLP, Suite 1700, 55 Second Street, San Francisco, CA, 94105, US

(73) Assignee: VIA Technologies, Inc.

(21) Appl. No.: 11/599,706

(22) Filed: Nov. 15, 2006

Related U.S. Application Data
(60) Provisional application No. 60/740,104, filed on Nov. 28, 2005.

(51) Int. Cl. H01L 29/76

(52) U.S. Cl. 257/372; 257/E27.063; 257/409

(57) ABSTRACT

This invention discloses a semiconductor device with latch-up prevention mechanisms. According to one embodiment, it comprises a first N-type region, wherein one or more P-type metal-oxide-semiconductor (PMOS) devices are disposed therein, a second N-type region adjacent to the first N-type region, wherein one or more PMOS devices are also disposed therein, and a P-type region disposed between the first and second N-type regions, wherein one or more guard rings are disposed therein, so that the semiconductor device is more immune to latch-up.

### CROSS REFERENCE

The present application claims the benefit of U.S. Provisional Application Ser. No. 60/740,104, which was filed on Nov. 28, 2005.

### BACKGROUND

The present invention relates generally to semiconductor devices, and, more particularly, to the prevention of latch-up in semiconductor devices.

Latch-up is defined as the creation of a low impedance path between power supply rails (a positive power supply voltage, or Vdd, and a complimentary low power supply voltage, or GND) as a result of triggering a parasitic device. In this condition, excessive current flow is possible, and a potentially destructive situation exists. After even a very short period of time in this condition, the device in which it occurs can be destroyed or weakened and potential damage can also occur to other components in the system.

A cause of latch-up as stated earlier, is a result of triggering a parasitic device, a silicon controlled rectifier (SCR) in effect, formed by a four-layer pnpn device of at least one pnp and at least one npn bipolar transistors connected as shown in FIG. 1A. The SCR is a normally off device in a “blocking state”, in which negligible current flows, but conducts from a node A to a node K only if an excitation is applied to a gate G.

Referring to FIG. 1A, the SCR conducts as a result of current from the gate G injected into the base of a npn bipolar transistor Q2, which causes current flow in the base-emitter junction of the a pnp bipolar transistor Q1. The pnp bipolar transistor Q1 turns on causing further current to be injected into the base of the npn bipolar transistor Q2. This positive feedback condition ensures that both bipolar transistors, Q1 and Q2, saturate. The current flowing through one bipolar transistor, Q1 or Q2, ensures that the other transistor remains in saturation. Then the SCR is said to be “latched”.

Once being latched, the SCR no longer depends on the trigger source applied to the gate G, a continual low-impedance path exists between the node A and the node K. Since the trigger source needs not to be constantly present, and removing it will not turn off the SCR. It could simply be a spike or a glitch. If, however, the voltage applied across the SCR can be reduced or the current flowing through it can be decreased to a point where it falls below a holding current value, Ih, as shown in FIG. 1B, the SCR will be switched off.

FIG. 2A shows a traditional complimentary metal-oxide-semiconductor (CMOS) structure, which forms a pair of parasitic bipolar transistors, Q1 and Q2 on a p-type semiconductor substrate. Rs and Rw represents resistances of a Psubstrate and an Nwell, respectively. FIG. 2B is a schematic diagram illustrating an equivalent parasitic SCR device formed by the two parasitic bipolar transistors, Q1 and Q2.

Traditional view of CMOS latch-up is a phenomenon between a P-type metal-oxide-semiconductor (PMOS) structure, which is connected to the Vdd, and an N-type metal-oxide-semiconductor (NMOS) structure, which is connected to GND. But parasitic SCR structure can also be formed between two adjacent PMOS cells as shown in FIGS. 4A and 4B. Even though being applied to the same voltage Vdd, the node V15 and V16 belong to different packaging pads, and during an electrostatic discharge (ESD) test, a latch-up condition can also be created in these parasitic SCR circuits.

Note that in FIG. 4B, there is a shallow-trench-isolation (STI) between the two adjacent PMOS structures. But with advanced processes, where devices are very close to each other, the STI, and even a guard ring are too shallow to prevent the latch-up from happening.

As such, what is desired is a robust latch-up prevention circuit structure between two adjacent PMOS structures.

### SUMMARY

This invention discloses a semiconductor circuit with an enhanced structure to avoid latch-up. According to a first aspect of the invention, a semiconductor circuit comprises a first N-type region, wherein one or more P-type metal-oxide-semiconductor (PMOS) devices are disposed therein, a second N-type region adjacent to the first N-type region, wherein one or more PMOS devices are disposed therein, and a P-type region disposed between the first and second N-type regions, wherein at least one guard ring is disposed therein.

According to a second aspect of the invention, a semiconductor circuit comprises a first doping region, wherein one or more semiconductor devices are disposed therein and coupled to a first pad and a first supply voltage, an N-type region adjacent to the first doping region wherein one or more P-type metal-oxide-semiconductor (PMOS) devices are disposed therein and coupled to a second pad and a second supply voltage higher than the first supply voltage, and a P-type region disposed between the first doping region and the N-type regions, wherein at least one guard ring is disposed therein.

According to a third aspect of the invention, a semiconductor circuit comprises a first N-type region, wherein one or more P-type metal-oxide-semiconductor (PMOS) transistors are disposed therein and coupled to a first pad and a first supply voltage, a second N-type region adjacent to the first N-type region, wherein one or more P-type metal-oxide-semiconductor (PMOS) devices are disposed therein and coupled to a second pad and a second supply voltage higher than the first supply voltage, and a P-type region disposed between the first and second N-type regions, wherein there is no guard ring disposed therein, wherein a minimum distance between a P+ region of a PMOS device in the second N-type region and a nearest N+ region of a semiconductor device in a first N-type region is not less than about 15 um.

According to a fourth aspect of the invention, the semiconductor circuit comprises a first doping region coupled to a first pad, wherein one or more semiconductor devices are disposed therein, a second doping region adjacent to the first doping region coupled to a second pad, wherein the second doping region is an Nwell, and one or more P-type metal-oxide-semiconductor (PMOS) devices are disposed therein, and a P-type region disposed between the first and second doping regions, wherein one or more deep P-type implant regions are disposed therein.

According to a fifth aspect of the invention, a semiconductor circuit comprises a first N-type region, wherein one or more first P-type metal-oxide-semiconductor (PMOS) devices are disposed therein and coupled to a first pad and a first supply voltage, a second N-type region adjacent to the first N-type region, wherein one or more second PMOS devices are disposed therein and coupled to a second pad and a second supply voltage higher than the first supply voltage, and wherein a minimum distance between a bulk pick-up N+ region in the first N-type region and a nearest P+ region of a PMOS device in the second N-type region is not less than about 15 um, a P-type region disposed between the first and second N-type regions, wherein at least one guard ring is disposed therein, and one or more deep P-type implant regions in the P-type region.

The construction and method of operation of the invention, however, together with additional objectives and advantages thereof will be best understood from the following description of specific embodiments when read in connection with the accompanying drawings.

### BRIEF DESCRIPTION OF THE DRAWINGS

FIG. 1A illustrates a basic SCR circuit structure.

FIG. 1B illustrates the current-voltage (I-V) characteristic of a latch-up phenomenon.

FIGS. 2A and 2B show a parasitic SCR and its equivalent circuit formed in a traditional CMOS structure.

FIG. 3 is a schematic diagram showing ESD protection circuits of two adjacent packaging pads.

FIGS. 4A through 4D illustrate parasitic SCR structures and their corresponding equivalent circuits formed in two adjacent P-cells that can be found in ESD protection circuits.

FIG. 5 illustrates a P+ guard ring disposed between two adjacent P-cells according to one embodiment of the present invention.

FIG. 6 illustrates an Nwell pick-up N+ moved away from the Nwell edge to increase Nwell resistance in the parasitic SCR according to another embodiment of the present invention.

FIG. 7 illustrates a deep N+ implant added beneath a Nwell pick-up N+ of a PMOS device according to yet another embodiment of the present invention.

FIG. 8 illustrates a deep P+ implant added beneath a STI between two adjacent Nwells according to yet another embodiment of the present invention.

### DESCRIPTION

The present invention discloses layout and implant methods for preventing latch-up between two metal-oxide-semiconductor (MOS) devices, particularly in ESD protection circuits.

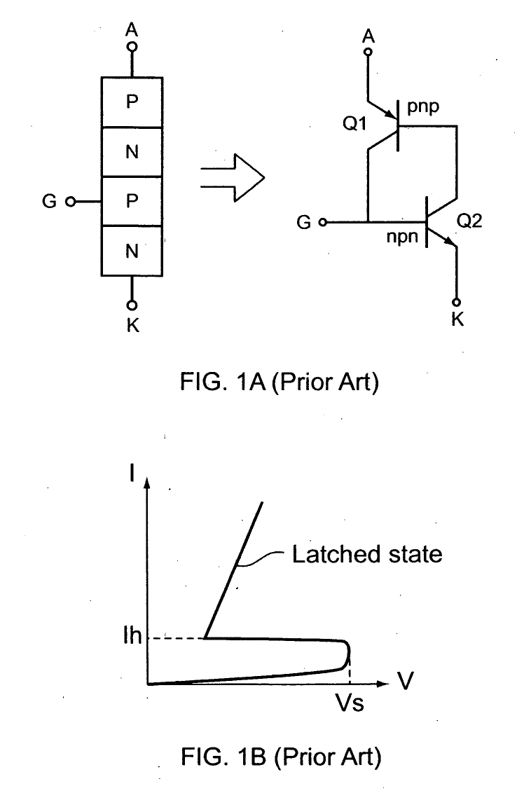

FIG. 1A illustrates a basic silicon controlled rectifier (SCR) circuit structure, formed by a four-layer pnpn device 100 of at least one pnp bipolar transistor Q1 and at least one npn bipolar transistor Q2. The SCR is a normally off device in a “blocking state”, in which negligible current flows, but conducts from a node A to a node K only if an excitation is applied to a gate G.

FIG. 1B illustrates the current-voltage (I-V) characteristic of the SCR shown in FIG. 1A. When a voltage between node A and node K exceed a voltage Vs as being triggered, the SCR will latch up with the current flowing through it drastically rises. But when the current falls below a holding current value, Ih, the SCR will be switched off.

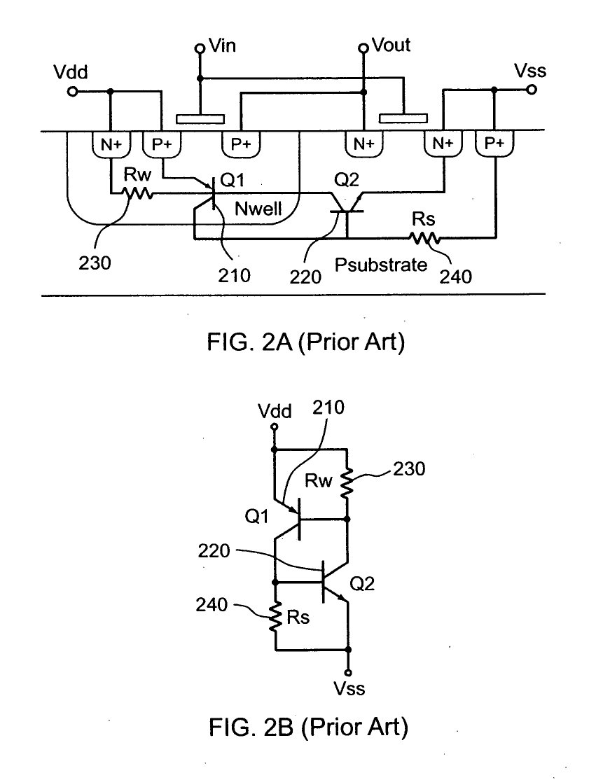

FIGS. 2A and 2B shows a parasitic SCR existing in a traditional complementary metal-oxide-semiconductor (CMOS) structure and its equivalent circuit, respectively. Referring to FIG. 2A, P+—Nwell—Psubstrate in a P-cell forms a pnp bipolar transistor 210. Nwell—Psubstrate—N+ in an N-cell forms an npn bipolar transistor 220. The higher the Nwell resistance 230 is, the easier the pnp bipolar transistor 210 can be triggered. Higher Psubstrate resistance 240 also makes the npn bipolar transistor 220 easier to trigger. So in order to prevent the parasitic SCR from latching up, both the Nwell and the Psubstrate resistances should be kept at a minimum.

Conventionally, guard rings are widely used to prevent latch-ups between P-cell and N-cell in a CMOS circuit. A guard ring for a P-cell comprises a P+ active region connected to a low supply voltage (GND) outside the Nwell. A guard ring for an N-cell comprises an N+ active region connected to a complementary high supply voltage (Vdd). But parasitic SCR can also be found between two adjacent P-cells, which are traditionally not protected by guard rings.

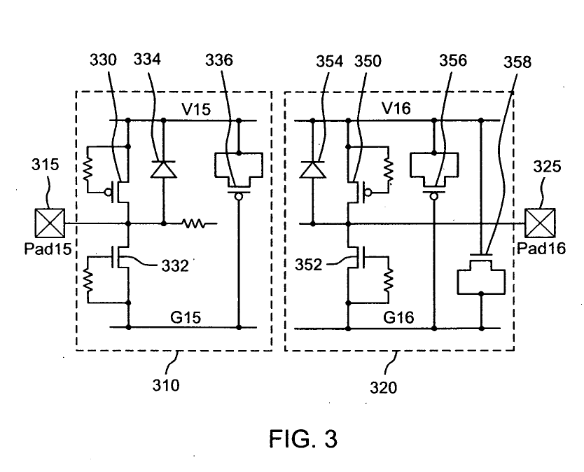

FIG. 3 is a schematic diagram showing ESD protection circuits 310 and 320 for two adjacent packaging pads 315 and 325, respectively. P-type metal-oxide-semiconductor (PMOS) transistors 330 and 350 are connected as reversed biased diodes, so are N-type metal-oxide-semiconductor (NMOS) transistors 332 and 352. The ESD protection circuits 310 and 320 also include junction diodes 334 and 354, PMOS capacitors 336 and 356, and NMOS capacitor 358. The power Vdd is connected to the pad 15's ESD protection circuit 310 at a node V15, while the GND is connected to the ESD protection circuit 310 at a node G15. The Vcc is connected to the pad 16's ESD protection circuit 320 at a node V16, while the GND is connected to the pad 16's ESD protection circuit 320 at a node G16. Among these ESD protection devices of two adjacent pads 315 and 325, parasitic SCR structures can be found between two P-cells. The power Vdd and the power Vcc have different voltage levels for driving the transistors. For-example, the Vdd is 3.3 V and the Vcc is 1.5 V.

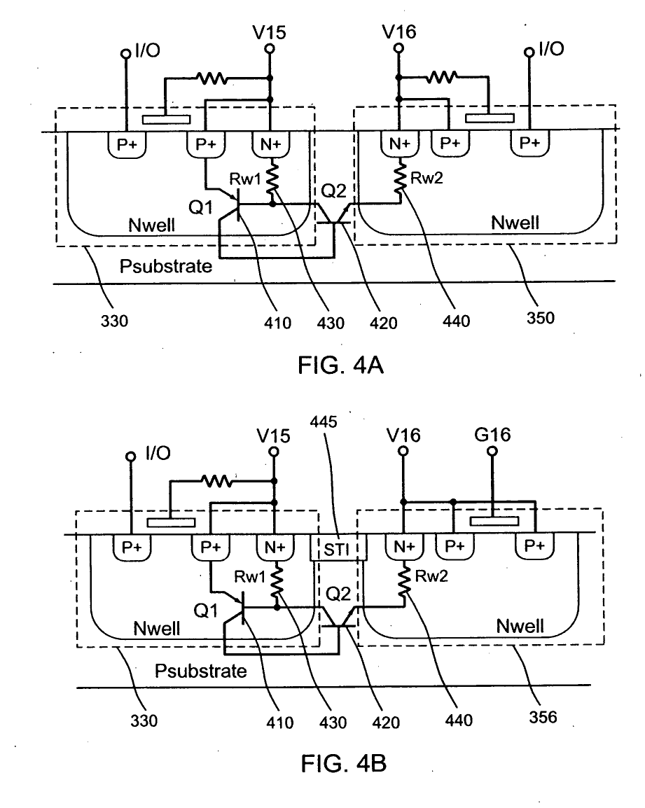

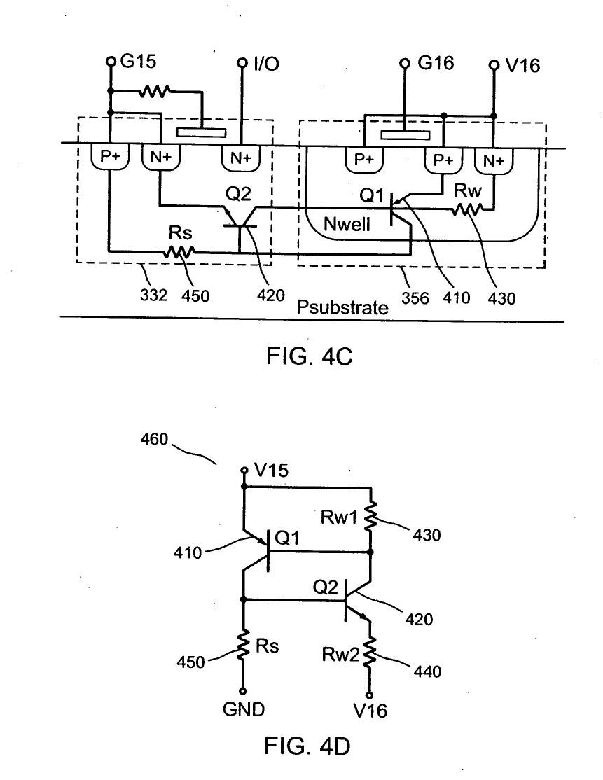

FIGS. 4A through 4D illustrate parasitic SCR structures and their corresponding equivalent circuit formed in two adjacent P-cells as well as between a P-cell and an N-cell. FIG. 4A shows two PMOS transistors 330 and 350 belonging to two different P-cells disposed next to each other. Parasitic bipolar transistors 410 and 420 form a SCR as shown in FIG. 4A. Note that like elements in the various figures are labeled with like reference numbers and are therefore not discussed again.

FIG. 4B shows the PMOS transistor 330 and the PMOS capacitor 356 are disposed next to each other. The PMOS transistor 330 and the PMOS capacitor 356 belong to two different P-cells. A shallow-trench-isolation (STI) 445 separates the PMOS transistor 330 and the PMOS capacitor 356. But the STI 445 is quite shallow, a parasitic npn bipolar transistor 420 can still be formed underneath the STI 445. So a parasitic SCR can also be,formed in this structure as shown in FIG. 4B.

FIG. 4C shows the NMOS transistor 332 and the PMOS capacitor 356 are disposed next to each other. Parasitic bipolar transistors 410 and 420 again form a SCR.

FIG. 4D is a schematic diagram illustrating an equivalent circuit to the parasitic SCRs shown in FIG. 4A˜4C. Referring to FIG. 4A˜4D, the bipolar transistor 410 is formed by P+—Nwell—Psubstrate. The bipolar transistor 420 is formed by Nwell—Psubstrate—N+ (through Nwell). During a latch-up test, a node V15 and a node V16 are coupled to the power Vdd and Vcc, respectively. The unexpected impulse on the power Vdd may turn the parasitic SCR 460 into latch-up. Then Nwell resistors 430 and 440 and a Psubstrate resistor 450 determine how well the parasitic SCR 460 is immune to latch-up. In general, decreasing the Nwell resistor 430 makes the bipolar transistors 410 harder to turn on, and decreasing the Psubstrate resistor 450 makes the bipolar transistor 420 harder to turn on. On the other hand, increasing the Nwell resistor 440 limits the current flowing through the SCR structure. So all these resistance modifications can boost latch-up immunity for the parasitic SRC 460. Based on this understanding, the present invention proposes following embodiments to improve the latch-up immunity between two adjacent P-cells.

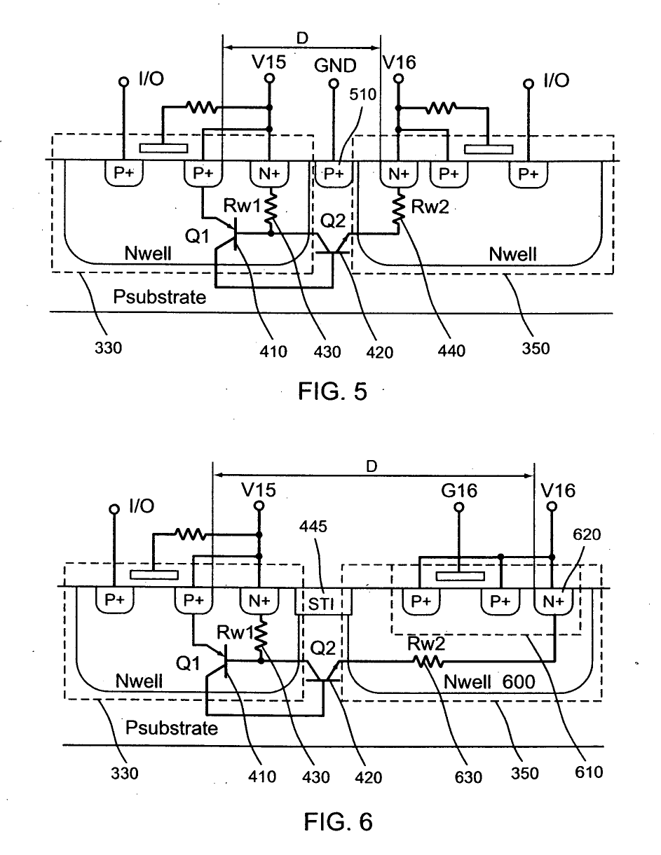

FIG. 5 illustrates a P+ guard ring 510 disposed between two adjacent P-cells 330 and 350 according to one embodiment of the present invention. The P+ guard ring reduces the resistance value of the Psubstrate resistor 450 shown in FIG. 4C. As a layout rule, the minimum distance between an Nwell pick-up (N+) and nearest P+ in the PMOS device is not in the same Nwell (distance D as shown in FIG. 5) is about 10 um.

FIG. 6 illustrates a Nwell pick-up (N+) 620 for a PMOS capacitor 610 is moved away from the edge of the Nwell 600 to increase the resistance of the Nwell resistor 630. As a layout rule, the minimum distance between the N+ 620 and the nearest P+ in the PMOS device is not in the same Nwell 600 (distance D as shown in FIG. 6) is about 15 um. The Nwell resistor 630 is equivalent to the Nwell resistor 440 shown in FIG. 4C.

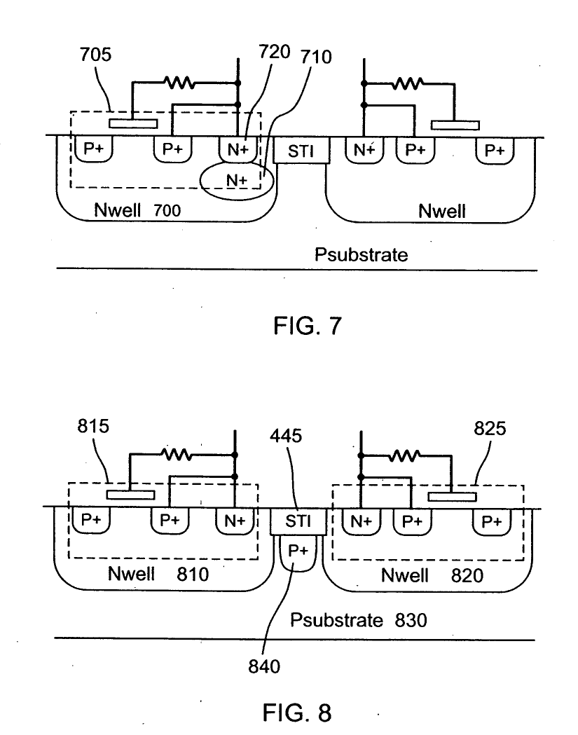

FIG. 7 illustrates a deep N+ implant 710 added beneath the Nwell pick-up (N+) 720 of a P-cell according to yet another embodiment of the present invention. Deep implant ions are implanted with high energy, so that they can penetrate deeper into a semiconductor substrate. The deep N+ implant 710 is to reduce the parasitic resistance of the Nwell 700, which is equivalent to the Nwell resistor 430 shown in FIG. 4C.

FIG. 8 illustrates a deep P+ implant 840 added beneath a STI 445 between two adjacent Nwells 810 and 820 according to yet another embodiment of the present invention. Nwell 810 contains a PMOS transistor 815 and Nwell 820 contains a PMOS transistor 825. Nwells 810 and 820 are next to each other, but are separated by a region of Psubstrate 830. The deep P+ implant 840 is also to reduce the resistance value of the Psubstrate resistor 450 shown in FIG. 4C. On the other hand, P+ implant 840 will make the npn (Q2) bipolar transistor degrade because the high-concentration of the base of Q2 will induce lower p-Gain.

The structures for reducing resistance of the Psubstrate resistor 450 and the resistance of the Nwell resistor 430, as well as increasing the resistance of the Nwell resistor 440 as shown in FIGS. 5 through 8 are effective ways to improve latch-up immunities between two adjacent P-cells. Even though these embodiments shows only structures for preventing latch-up between two adjacent P-cells, one who has skills in the art would be able to apply the structures according to the present invention to adjacent N-cells and P-cells, particularly to cells that form part of ESD circuits.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A semiconductor circuit comprising:
a first N-type region, wherein one or more P-type metal-oxide-semiconductor (PMOS) devices are disposed therein;
a second N-type region adjacent to the first N-type region, wherein one or more PMOS devices are disposed therein; and
a P-type region disposed between the first and second N-type regions, wherein at least one guard ring is disposed therein.

2. The semiconductor circuit of claim 1, wherein the first or second N-type region is an Nwell.

3. The semiconductor circuit of claim 2, wherein a minimum distance between a bulk pick-up N+ region in the first N-type region and a nearest P+ region of a PMOS device in the second N-type region is not less than about 15 um.

4. The semiconductor circuit of claim 1, wherein the first PMOS device is coupled to a first supply voltage and the second PMOS device is coupled to a second supply voltage larger than the first supply voltage.

5. The semiconductor circuit of claim 4, wherein the guard ring further comprises one or more P+ regions which are connected to a third low supply voltage (GND), which is lower than either the first or second supply voltage.

6. The semiconductor circuit of claim 1, wherein the PMOS device disposed in either the first or second N-type region further comprises one or more deep N-type implant regions beneath a bulk pick-up N+ region of the PMOS device.

7. The semiconductor circuit of claim 1, wherein the P-type region further comprises one or more shallow-trench-isolation (STI) regions.

8. The semiconductor circuit of claim 1, wherein the P-type region further comprises one or more deep P-type implant regions.

9. A semiconductor circuit comprising:
a first doping region, wherein one or more semiconductor devices are disposed therein and coupled to a first pad and a first supply voltage;
a N-type region adjacent to the first doping region wherein one or more P-type metal-oxide-semiconductor (PMOS) devices are disposed therein and coupled to a second pad and a second supply voltage higher than the first supply voltage; and
a P-type region disposed between the first doping region and the N-type regions, wherein at least one guard ring is disposed therein.

10. The semiconductor circuit of claim 9, wherein the first doping region is an Nwell, and the semiconductor devices are PMOS devices.

11. The semiconductor circuit of claim 9, wherein the first doping region is a P-type region and the semiconductor devices are NMOS devices.

12. The semiconductor circuit of claim 9, wherein the guard ring further comprises one or more P+ regions, which are connected to a third low supply voltage (GND), which is lower than either the first or second supply voltage.

13. The semiconductor circuit of claim 9, wherein the PMOS device disposed in the N-type region further comprises one or more deep N-type implant regions beneath a bulk pick-up N+ region of the PMOS device.

14. A semiconductor circuit comprising:
a first N-type region, wherein one or more P-type metal-oxide-semiconductor (PMOS) transistors are disposed therein and coupled to a first pad and a first supply voltage;
a second N-type region adjacent to the first N-type region, wherein one or more P-type metal-oxide-semiconductor (PMOS) devices are disposed therein and coupled to a second pad and a second supply voltage higher than the first supply voltage; and
a P-type region disposed between the first and second N-type regions, wherein there is no guard ring disposed therein,
wherein a minimum distance between a P+ region of a PMOS device in the second N-type region and a nearest N+ region of a semiconductor device in a first N-type region is not less than about 15 um.

15. The semiconductor circuit of claim 14, wherein the first or second N-type region is an Nwell.

16. The semiconductor circuit of claim 14, wherein the PMOS device is a PMOS transistor or a PMOS capacitor.

17. The semiconductor circuit of claim 14, wherein the PMOS transistor disposed in the first N-type region further comprises one or more deep N-type implant regions beneath a bulk pick-up N+ region of the PMOS transistor.

18. The semiconductor circuit of claim 14, wherein the P-type region further comprises one or more shallow-trench-isolation (STI) regions.

19. The semiconductor circuit of claim 14, wherein the P-type region is a p-type semiconductor substrate.

20. The semiconductor circuit of claim 19, wherein the P-type region further comprises one or more deep P-type implant regions.

21. A semiconductor circuit comprising:
a first doping region coupled to a first pad, wherein one or more semiconductor devices are disposed therein;
a second doping region adjacent to the first doping region coupled to a second pad, wherein the second doping region is an Nwell, and one or more P-type metal-oxide-semiconductor (PMOS) devices are disposed therein; and
a P-type region disposed between the first and second doping regions, wherein one or more deep P-type implant regions are disposed therein.

22. The semiconductor circuit of claim 21, wherein the first doping region is an Nwell and the semiconductor device is a PMOS device.

23. The semiconductor circuit of claim 21, wherein the first doping region is a P-type region, and the semiconductor devices are NMOS devices.

24. The semiconductor circuit of claim 21, wherein the PMOS device disposed in the second doping region further comprises one or more deep N-type implant regions beneath a bulk pick-up N+ region of the PMOS device.

25. The semiconductor circuit of claim 21, wherein the P-type region further comprises one or more shallow-trench-isolation (STI) regions.

26. A semiconductor circuit comprising:
a first N-type region, wherein one or more first P-type metal-oxide-semiconductor (PMOS) devices are disposed therein and coupled to a first pad and a first supply voltage;
a second N-type region adjacent to the first N-type region, wherein one or more second PMOS devices are disposed therein and coupled to a second pad and a second supply voltage higher than the first supply voltage, and wherein a minimum distance between a bulk pick-up N+ region in the first N-type region and a nearest P+ region of a PMOS device in the second N-type region is not less than about 15 um;
a P-type region disposed between the first and second N-type regions, wherein at least one guard ring is disposed therein; and
one or more deep P-type implant regions in the P-type region.

27. The semiconductor circuit of claim 26, wherein the guard ring further comprises one or more P+ regions, which are connected to a third low supply voltage (GND), which is lower than either the first or second supply voltage.

28. The semiconductor circuit of claim 26, wherein the second PMOS device is a PMOS capacitor.

29. The semiconductor circuit of claim 26, wherein the P-type region is a p-type semiconductor substrate.
